(19) United States
(12) Patent Application Publication
(10) Pub. No.: US 2014/0361841 A1
(43) Pub. Date: Dec. 11, 2014

(54) SIGNAL GENERATION CIRCUIT, SIGNAL GENERATION APPARATUS, METHOD FOR MANUFACTURING SIGNAL GENERATION APPARATUS, ELECTRONIC APPARATUS, AND MOVING OBJECT

(71) Applicant: Seiko Epson Corporation, Tokyo (JP)

(72) Inventors: Mitsuaki SAWADA, Fujimi (JP); Tetsuya YONEMURA, Chino (JP)

(21) Appl. No.: 14/300,573

(22) Filed: Jun. 10, 2014

(30) Foreign Application Priority Data
Jun. 11, 2013 (JP) 2013-122566

(51) Int. Cl. H03L 7/08

(52) U.S. Cl. CPC H03L 7/08
USPC 331/18

(57) ABSTRACT

A signal generation circuit including a phase locked loop circuit that uses an oscillation section as a reference signal source and a switching section capable of switching a state in which a periodic signal from the oscillation section is outputted to a state in which a signal from the phase locked loop circuit is outputted.

### BACKGROUND

1. Technical Field

The present invention relates to a signal generation circuit, a signal generation apparatus including the signal generation circuit, a method for manufacturing the signal generation apparatus, an electronic apparatus including the signal generation circuit, and a moving object.

2. Related Art

As a signal generation circuit, there is a known signal generation circuit of related art including a phase locked loop (PLL) circuit described, for example, in JP-A-2002-271196.

Such a signal generation circuit includes a reference signal source for the phase locked loop circuit, and a crystal oscillator is used as the reference signal source in JP-A-2002-271196.

A phase locked loop circuit has a voltage-controlled oscillator built therein and performs a function of allowing the phase of a periodic signal from the voltage-controlled oscillator to be synchronized with the phase of a periodic signal inputted from the crystal oscillator to cause the precision of the periodic signal of the voltage-controlled oscillator to be equal to the precision of the periodic signal from the crystal oscillator.

The crystal oscillator is therefore required to output a high-precision periodic signal.

To increase the precision of the periodic signal from the crystal oscillator, necessary adjustment is made in accordance with required performance, for example, compensation of dependence of the frequency of the built-in crystal oscillator on temperature or what is called frequency-temperature characteristic adjustment, adjustment of the frequency at a reference temperature of 25° C. or any other value, and adjustment of the voltage or current level of the periodic signal.

To make the variety of adjustment described above or determine the necessity for the adjustment, the periodic signal from the crystal oscillator is measured on a standalone basis before the crystal oscillator is connected to the phase locked loop circuit.

On the other hand, to check or adjust the performance of the crystal oscillator in consideration of the load capacitance of a peripheral circuit for the crystal oscillator, such as the phase locked loop circuit, a sync signal from the crystal oscillator may be measured with the crystal oscillator connected to the phase locked loop circuit. In this case, the technology disclosed in JP-A-2004-72289 may be used as a technology required for the measurement.

That is, in addition to an output terminal through which the periodic signal from the phase locked loop circuit is outputted, it is typical to provide a dedicated output terminal through which the periodic signal from the crystal oscillator can be outputted.

In the case where the output terminal for the phase locked loop circuit and the output terminal for the crystal oscillator are provided as described above, however, the number of output terminals is undesirably greater than that in a case where the crystal oscillator is provided on a standalone basis.

The problematic configuration described above also requires a wiring substrate on which the signal generation circuit is mounted to have an output terminal for the crystal oscillator and an output terminal for the phase locked loop circuit, undesirably resulting in an increase in the size of the signal generation circuit and hence the size of an apparatus including the signal generation circuit.

### SUMMARY

An advantage of some aspects of the invention is to solve at least a part of the problems described above, and the invention can be implemented as the following forms or application examples.

### Application Example 1

A signal generation circuit according to this application example includes an oscillation section including an oscillation circuit and a first output terminal through which a periodic signal is outputted, a phase locked loop circuit so brought into conduction with the first output terminal that the oscillation section serves as a reference signal source and including a second output terminal, and a switching section including a signal output terminal and switching the state of a segment between the first output terminal and the signal output terminal from a conducting state to a non-conducting state and switching the state of a segment between the second output terminal and the signal output terminal to the conducting state.

According to this application example, since a state in which the signal output terminal and the first output terminal are brought into conduction with each other can be switched to a state in which the signal output terminal and the second output terminal are brought into conduction with each other, the periodic signal from the oscillation section or the periodic signal from the phase locked loop circuit can be switched to the other and the selected periodic signal can be outputted through the common signal output terminal. Therefore, a signal generation circuit capable of outputting a high-precision signal with an increase in the size thereof suppressed can be advantageously provided.

### Application Example 2

In the signal generation circuit according to the application example described above, it is preferable that the oscillation section further includes a control circuit that controls a characteristic of the periodic signal outputted through the first output terminal, and the oscillation section is capable of changing a function of the control circuit.

According to this application example, since the characteristic of the periodic signal from the oscillation section can be changed based on a result of measurement of the resonance signal, the periodic signal outputted by the oscillation section can be a high-precision periodic signal. Therefore, a signal generation circuit capable of outputting a high-precision signal with an increase in the size thereof suppressed can be advantageously provided.

### Application Example 3

It is preferable that the signal generation circuit according to the application example described above further includes a resonance section that supplies a resonance signal to the oscillation circuit.

According to this application example, since the state in which the signal output terminal and the first output terminal are brought into conduction with each other can be switched to the state in which the signal output terminal and the second output terminal are brought into conduction with each other, the periodic signal from the oscillation section or the periodic signal from the phase locked loop circuit can be switched to the other and the selected periodic signal can be outputted through the common signal output terminal. Further, the function of the resonance section can be checked and adjusted as required. Therefore, a signal generation circuit capable of outputting a high-precision signal with an increase in the size thereof suppressed can be advantageously provided.

### Application Example 4

A signal generation apparatus according to this application example includes an oscillation section including an oscillation circuit and a first output terminal through which a periodic signal is outputted, a phase locked loop circuit so brought into conduction with the first output terminal that the oscillation section serves as a reference signal source and including a second output terminal, a switching section including a signal output terminal, disposed in a first inter-terminal segment between the first output terminal and the signal output terminal and in a second inter-terminal segment between the second output terminal and the signal output terminal, and switching the state of a selected one of the inter-terminal segments to a conducting state and switching the state of the other inter-terminal segment to a non-conducting state, and a wiring substrate on which the oscillation section and the phase locked loop circuit are mounted and which has a terminal portion brought into conduction with the signal output terminal.

According to this application example, since the signal output terminal and the first output terminal can be brought into conduction with each other, the periodic signal from the oscillation section or the periodic signal from the phase locked loop circuit can be switched to the other and the selected periodic signal can be outputted through the signal output terminal. Therefore, a high-precision signal generation apparatus with an increase in the size of the signal output terminal suppressed can be advantageously provided.

### Application Example 5

In the signal generation apparatus according to the application example described above, it is preferable that the oscillation circuit, the phase locked loop circuit, and the switching section are provided in a single semiconductor substrate.

According to this application example, for example, a signal generation apparatus capable of outputting a high-precision signal with an increase in the size thereof suppressed based on an integration technology can be advantageously provided.

### Application Example 6

It is preferable that the signal generation apparatus according to the application example described above further includes a resonance section that supplies a periodic signal to the oscillation circuit.

According to this application example, a signal generation apparatus capable of outputting a high-precision signal with an increase in the size thereof suppressed can be advantageously provided.

### Application Example 7

In the signal generation apparatus according to the application example described above, it is preferable that the oscillation section further includes a control circuit that controls a characteristic of the signal outputted through the first output terminal.

According to this application example, a signal generation apparatus capable of outputting a high-precision periodic signal with an increase in the size thereof suppressed can be advantageously provided.

### Application Example 8

In the signal generation apparatus according to the application example described above, it is preferable that the switching section keeps the state of the second inter-terminal segment conducting.

According to this application example, when the signal generation apparatus is used, the switching section does not need to perform the switching operation, whereby a high-precision signal can be advantageously outputted in a relatively short period accordingly with an increase in the size of the apparatus suppressed.

### Application Example 9

A method for manufacturing a signal generation apparatus according to this application example includes providing a signal generation apparatus including an oscillation section having a resonance section, an oscillation circuit to which a resonance signal from the resonance section is supplied, and a first output terminal through which a periodic signal is outputted, a phase locked loop circuit so brought into conduction with the first output terminal that the oscillation section serves as a reference signal source and having a second output terminal, and a switching section having a signal output terminal and switching a state in which the first output terminal and the signal output terminal are brought into conduction with each other; outputting the periodic signal from the oscillation section through the signal output terminal, measuring the periodic signal, and adjusting a function of the oscillation section based on a result of the measurement in the state in which the first output terminal and the signal output terminal are brought into conduction with each other; and controlling the switching section to bring the second output terminal and the signal output terminal into conduction with each other.

According to this application example, even when the oscillation section and the phase locked loop circuit are connected to each other, the switching section can switch the periodic signal from the oscillation section or the periodic signal from the phase locked loop circuit to the other and output the selected periodic signal through the signal output terminal. As a result, the function of the oscillation section can be checked in consideration of influence of electrical characteristics of peripheral circuits for the oscillation section, whereby a signal generation apparatus capable of outputting a high-precision signal with an increase in the size thereof suppressed can be advantageously manufactured.

### Application Example 10

It is preferable that the method for manufacturing a signal generation apparatus according to the application example described above further includes adjusting the function of the oscillation section after the measurement of the periodic signal.

According to this application example, since a function of the oscillation section is adjusted in accordance with the phase locked loop circuit, operating performance of the phase locked loop circuit can be improved, whereby a signal generation apparatus capable of outputting a high-precision signal with an increase in the size thereof suppressed can be advantageously manufactured.

### Application Example 11

It is preferable that the method for manufacturing a signal generation apparatus according to the application example described above further includes adjusting the function of the phase locked loop circuit after the adjustment of the function of the oscillation section.

According to this application example, since the function of the phase locked loop circuit can be adjusted in accordance with the oscillation section the function of which has been adjusted, operating performance of the phase locked loop circuit can be improved, whereby a signal generation apparatus capable of outputting a high-precision signal with an increase in the size thereof suppressed can be advantageously manufactured.

### Application Example 12

In the method for manufacturing a signal generation apparatus according to the application example described above, it is preferable that a function of the phase locked loop circuit is disabled in the measurement of the periodic signal.

According to this application example, since the magnitude of noise signal produced by the phase locked loop circuit is suppressed when the function of the oscillation section is checked, the function of the oscillation section can be adjusted in a highly precise manner, whereby a signal generation apparatus capable of outputting a high-precision signal with an increase in the size thereof suppressed can be advantageously manufactured.

### Application Example 13

In the method for manufacturing a signal generation apparatus according to the application example described above, it is preferable that a power source voltage is supplied to the phase locked loop circuit in the measurement of the periodic signal.

According to this application example, since the function of the oscillation section can be checked in consideration of an electrical characteristic of the phase locked loop circuit, the function of the oscillation section can be adjusted in a highly precise manner, whereby a signal generation apparatus capable of outputting a high-precision signal with an increase in the size thereof suppressed can be advantageously manufactured.

### Application Example 14

An electronic apparatus according to this application example includes the signal generation circuit according to the application example described above.

According to this application example, an electronic apparatus having high performance with an increase in the size thereof suppressed can be advantageously provided.

### Application Example 15

A moving object according to this application example includes the signal generation circuit according to the application example described above.

According to this application example, a moving object having high performance with an increase in the size thereof suppressed can be advantageously provided.

### BRIEF DESCRIPTION OF THE DRAWINGS

The invention will be described with reference to the accompanying drawings, wherein like numbers reference like elements.

FIG. 1 shows a signal generation circuit according to a first embodiment.

FIGS. 2A and 2B show a signal generation apparatus including the signal generation circuit according to the first embodiment.

FIG. 3 shows a method for manufacturing a signal generation apparatus according to the first embodiment.

FIG. 4 shows a signal generation circuit according to a second embodiment.

FIG. 5 shows a method for manufacturing a signal generation apparatus including the signal generation circuit according to the second embodiment.

FIGS. 6A and 6B show methods for manufacturing a signal generation apparatus according to Variation 1.

FIG. 7 shows a signal generation apparatus according to Variation 2.

FIG. 8 shows a signal generation apparatus according to Variation 3.

FIG. 9 shows an example of an electronic apparatus including the signal generation circuit according to any of the embodiments.

FIG. 10 shows an example of a moving object including the signal generation circuit according to any of the embodiments.

### DESCRIPTION OF EXEMPLARY EMBODIMENTS

Embodiments of the invention will be described below with reference to the drawings. In the following figures, the scale of each layer or member is intentionally differentiated from the actual scale thereof to enlarge the layer or member to a recognizable size.

### First Embodiment

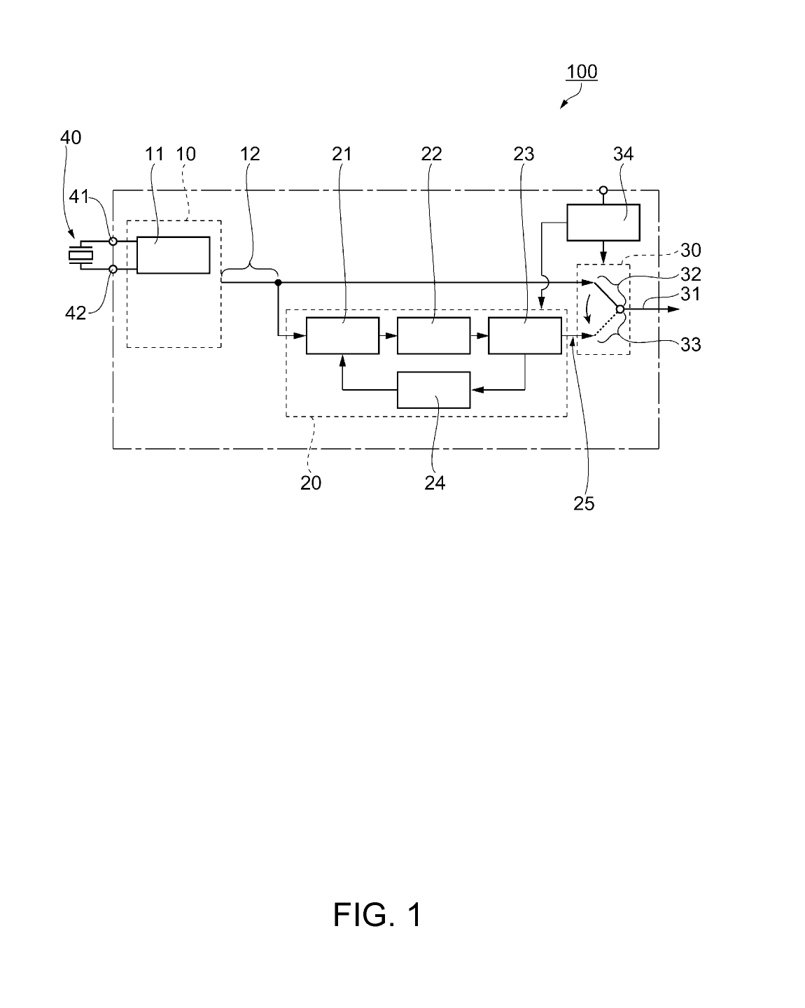

FIG. 1 is a circuit diagram of a signal generation circuit 100 according to a first embodiment. A description will first be made of a schematic configuration of the signal generation circuit 100 according to the first embodiment.

The signal generation circuit 100 in the present embodiment includes at least an oscillation section 10, a phase locked loop circuit 20, which uses the oscillation section 10 as a reference signal source, and a switching section 30. In the present embodiment, the signal generation circuit 100 further includes a resonance section 40.

The oscillation section 10 includes at least an oscillation circuit 11, which receives a resonance signal from the resonance section 40 and activates oscillation in response to the supplied resonance signal, and a first output terminal 12, which is a transmission path through which a periodic signal outputted from the oscillation circuit 11 is transmitted not only to the phase locked loop circuit 20 but also to the switching section 30.

The phase locked loop circuit 20 includes, for example, a phase comparator circuit 21, a filter circuit 22, a voltage-controlled oscillator circuit 23, and a divider circuit 24.

The phase comparator circuit 21 receives the following two signals: the periodic signal outputted from the oscillation section 10 and transmitted through the first output terminal 12; and a divided periodic signal from the voltage-controlled oscillator circuit 23 via the divider circuit 24. The phase comparator circuit 21 supplies the filter circuit 22 with a phase difference signal according to a phase difference between the two periodic signals.

The filter circuit 22 is, for example, what is called a lowpass filter that removes a high frequency band signal based on a cut-off frequency and outputs a low frequency band signal with little attenuation thereof. The filter circuit 22 extracts a low frequency signal based on the supplied phase difference signal and supplies the voltage-controlled oscillator circuit 23 with the low frequency signal as a control voltage.

The voltage-controlled oscillator circuit 23 is, for example, an LC oscillation circuit including a resonance circuit formed of an inductor and a capacitor and controls the capacitance of a variable capacitance diode, a capacitance array circuit, or any other component built in the voltage-controlled oscillator circuit 23 in accordance with the control voltage supplied from the filter circuit 22. The phase locked loop circuit 20 then enters a “locked” state in which the voltage-controlled oscillator circuit 23 outputs a periodic signal having a desired frequency in accordance with the amount of controlled capacitance. The periodic signal outputted from the voltage-controlled oscillator circuit 23 is supplied to the switching section 30 via a second output terminal 25, which is another transmission path.

The switching section 30 at least has a function of switching the state of a first inter-terminal segment 32 between a signal output terminal 31, which is a transmission path through which an outputted periodic signal is transmitted, and the first output terminal 12 from a conducting state to a non-conducting state (state indicated by solid line) and switching the state of a second inter-terminal segment 33 between the second output terminal 25 and the signal output terminal 31 from the non-conducting state to the conducting state (state indicated by dotted line).

In this case, a signal processing circuit may be present between the first output terminal 12 and the switching section 30 and may process the periodic signal outputted by the oscillation section 10 and output the processed signal to the switching section 30. The signal processing circuit is, for example, a divider circuit, a multiplier circuit, a waveform shaping circuit, a buffer circuit, or an amplifier circuit.

Further, a signal processing circuit may be present between the second output terminal 25 and the switching section 30 and may process the periodic signal outputted by the phase locked loop circuit 20 and output the processed signal to the switching section 30. The signal processing circuit is, for example, a divider circuit, a multiplier circuit, a waveform shaping circuit, a buffer circuit, or an amplifier circuit.

Moreover, a computation section or any other circuit may be present between the first output terminal 12 and the phase locked loop circuit 20.

The signal generation circuit 100 further includes a control section 34, which sends a control signal to the switching section 30 in accordance with a supplied instruction signal to control the switching action of the switching section 30. The control section 34 may further output a control signal that controls adjustment of the function of the phase locked loop circuit 20.

According to the thus configured signal generation circuit 100, the signal output terminal 31, through which the periodic signal from the phase locked loop circuit 20 is outputted, can be used to measure the periodic signal from the oscillation section 10, whereby the function of the oscillation section 10 can be checked.

Since a result of the checking is obtained based on the state in which the oscillation section 10 and the phase locked loop circuit 20 are connected to each other, the result shows a state closer to actual conditions under which the signal generation circuit 100 is used than in a case where the oscillation section 10 is checked on a standalone basis.

When the result of the checking shows that the function of the oscillation section 10 is inappropriate, the oscillation section 10 can be replaced or adjusted, or the resonance section 40 can be replaced or the frequency or any other parameter thereof can be adjusted. The resultant signal generation circuit 100 can therefore output a high-precision signal without provision of a dedicated terminal through which the periodic signal from the oscillation section 10 is outputted.

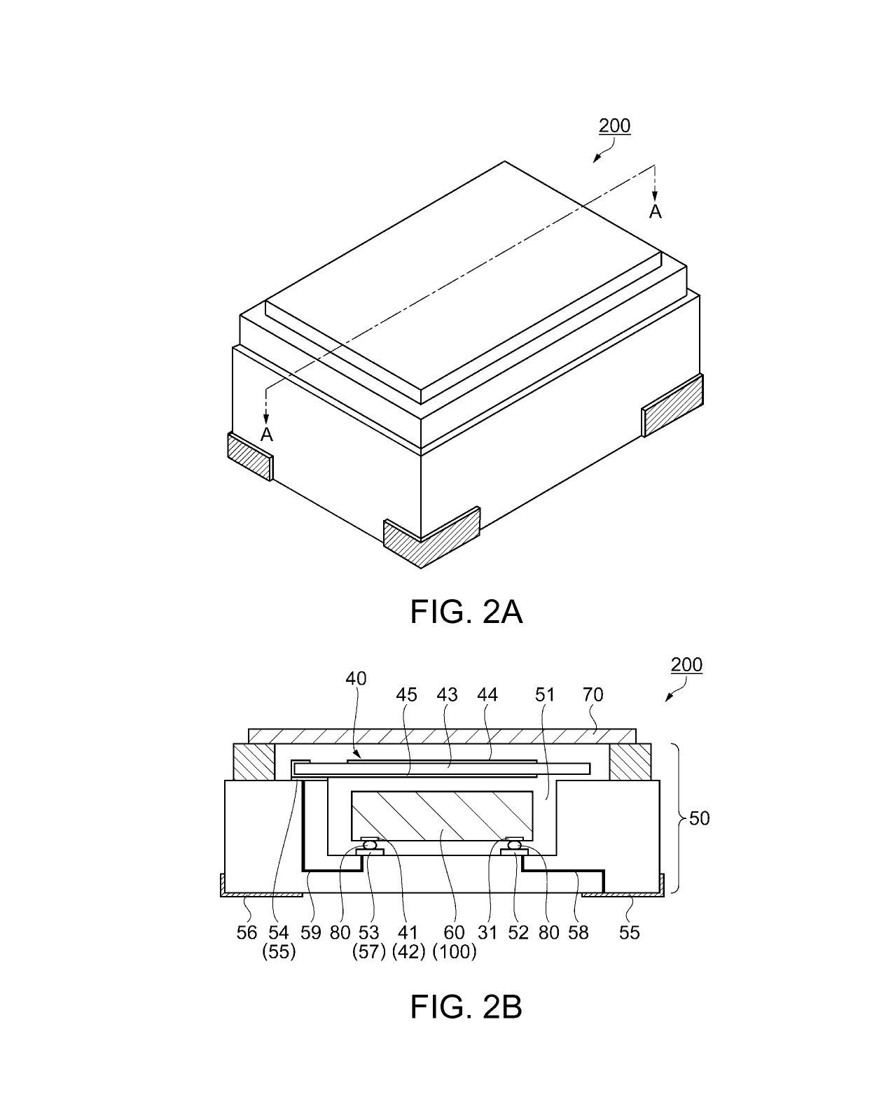

FIGS. 2A and 2B show a schematic configuration of a signal generation apparatus 200 including the signal generation circuit 100 described above.

FIGS. 2A and 2B describe the signal generation apparatus 200 including the signal generation circuit 100. FIG. 2A is a perspective view showing the exterior appearance of the signal generation apparatus 200, and FIG. 2B is a front cross-sectional view of the signal generation apparatus 200 taken along the line A-A in FIG. 2A in the direction indicated by the arrow.

The signal generation apparatus 200 in the present embodiment only needs to include at least a semiconductor integrated device 60 on a wiring substrate 50. In the present embodiment, the resonance section 40 and a lid 70 are also mounted on the wiring substrate 50.

The wiring substrate 50 is made, for example, of a ceramic material or any other insulating material and has a conductor path provided therein. The wiring substrate 50 has a recess 51, which is used as an accommodation space, terminal portions 52, 53, and 54, each of which is disposed on a surface in the recess 51, terminal portions 55 and 56, which are disposed on a rear surface of the wiring substrate 50 or a surface thereof facing away from the recess 51, and a terminal portion 57 (not shown).

The terminal portion 52 and the terminal portion 55 are brought into conduction with each other via a conductor path 58 provided in the wiring substrate 50. The terminal portion 53 and the terminal portion 54 are brought into conduction with each other via a conductor path 59 provided in the wiring substrate 50. The terminal portion 55 and the terminal portion 57 are brought into conduction with each other via a conductor path (not shown) provided in the wiring substrate 50.

The number of terminal portions may differ from the number described above as required.

The semiconductor integrated device 60 is so configured that the signal generation circuit 100 shown in FIG. 1 except, for example, the resonance section 40 is formed in a silicon semiconductor substrate and the signal output terminal 31, a terminal 41, which is brought into conduction with the resonance section 40, and a terminal 42 are exposed through a surface of the semiconductor integrated device 60.

The semiconductor integrated device 60 is so mounted on the wiring substrate 50 that the signal output terminal 31 is brought into conduction with the terminal portion 52, the terminal 41 is brought into conduction with the terminal portion 53, and the terminal 42 is brought into conduction with the terminal portion 57. In the present embodiment, the semiconductor integrated device 60 is placed in the recess 51 via bonding members 80, such as metal bumps, in a flip-chip mounting process.

The semiconductor integrated device 60 is not necessarily connected in a flip-chip mounting process and may, be so connected that terminal 41 and the terminal portion 53 are brought into conduction with each other and the terminal 42 and the terminal portion 57 are brought into conduction with each other, for example, in a wire bonding process.

The resonance section 40 as an oscillation piece may be an AT-cut crystal oscillation piece, a tuning fork crystal oscillation piece, or any other piezoelectric oscillation piece. The resonance section 40 may instead be produced by processing a silicon material by using an MEMS (micro electro mechanical systems) technology. The resonance section 40, when it is produced as a piezoelectric oscillation piece, may be formed of a plurality of resonators formed in a single piezoelectric substrate.

The resonance section 40, when it is formed of an AT-cut crystal oscillation piece, includes a first excitation electrode 44 on one principal surface of a crystal substrate 43 and a second excitation electrode 45 on the other principal surface or a rear surface facing away from the one principal surface or a front surface.

The first excitation electrode 44 and the terminal portion 55 are so connected to each other that they are brought into conduction with each other via a conductive adhesive or any other bonding medium. Further, the second excitation electrode 45 and the terminal portion 54 are so connected to each other that they are brought into conduction with each other via a conductive adhesive or any other bonding medium. The conductive adhesive described above also allows the resonance section 40 to be fixed to the wiring substrate 50.

As a result, the resonance section 40 and the oscillation circuit 11 are brought into conduction with each other, which allows the oscillation section 10 to perform an oscillation function. The oscillation section 10 specifically has a function of activating overtone oscillation or a fundamental wave oscillation.

The lid 70, for example, has a plate-like shape and is made of a metal. The lid 70 is so fixed to the wiring substrate 50 in a seam welding process that the lid 70 covers the resonance section 40 and the semiconductor integrated device 60 and maintains the recess 51 hermetically sealed. Further, the lid 70 and the wiring substrate 50 form a package.

The above description has been made with reference to the case where the semiconductor integrated device 60 includes the signal generation circuit 100 shown in FIG. 1, but the semiconductor integrated device 60 may instead include a circuit excluding a circuit element that is not readily integrated, such as an inductor circuit that forms the voltage-controlled oscillator circuit 23, but including the oscillation circuit, the phase locked loop circuit, and the switching section. In this case, an inductor circuit element and other similar circuit elements can be provided as discrete parts separate from the semiconductor integrated device 60 and can be mounted on the wiring substrate 50.

In the thus configured signal generation apparatus 200, the phase locked loop circuit 20 and the oscillation section 10 are connected to each other when the oscillation section 10 is formed.

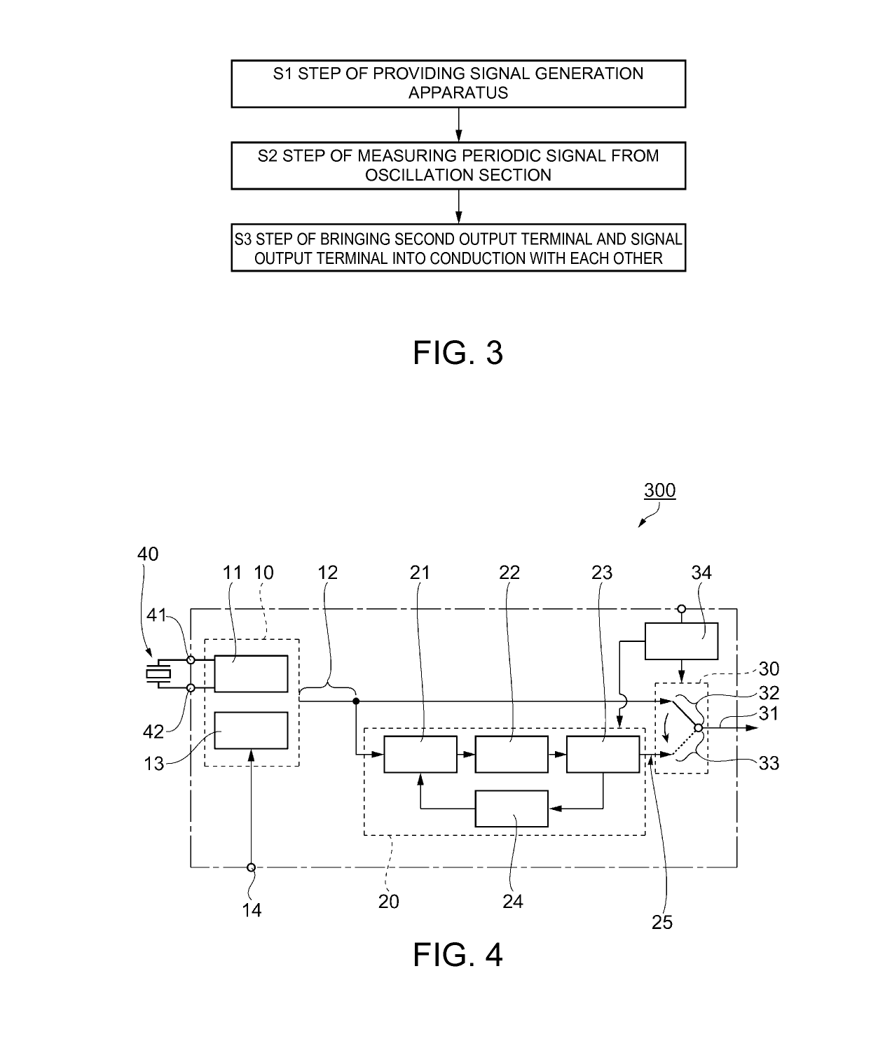

FIG. 3 describes a method for manufacturing the signal generation apparatus 200.

First, in step S1, the signal generation apparatus 200 assembled, for example, as shown in FIGS. 2A and 2B is provided.

Next, in step S2, the periodic signal from the oscillation section 10 outputted via the signal output terminal 31 and through the terminal portion 55 is measured. In this process, the switching section 30 sets the first and second inter-terminal segments 32, 33 in such a way that the first inter-terminal segment 32 is conducting but the second inter-terminal segment 33 is not conducting (which means that no signal from phase locked loop circuit 20 is transmitted).

The setting described above made by the switching section 30 may be made after the signal generation apparatus 200 is assembled. However, making the setting described above before the signal generation apparatus 200 is assembled but when the semiconductor integrated device 60 is formed eliminates the necessity to control the switching section 30 after the signal generation apparatus 200 is assembled, whereby it is expected that manufacturing efficiency is improved.

Further, in step S2, the function of the phase locked loop circuit 20 may be activated, but the function is desirably disabled.

In this case, the state in which the function of the phase locked loop circuit 20 is disabled does not necessarily strictly require that no power source voltage is applied to the phase locked loop circuit 20, but the phase locked loop circuit 20 only needs to produce no periodic signal. When the function of the phase locked loop circuit 20 is enabled, the periodic signal from the oscillation section 10 is mixed with a noise signal produced by the phase locked loop circuit 20, and precision of the measurement undesirably decreases. Disabling the function of the phase locked loop circuit 20 can avoid the situation described above.

It is noted that the signal generation apparatus 200 can be manufacture irrespective of the state of the phase locked loop circuit 20, that is, the state in which the function of the phase locked loop circuit 20 is disabled and the state in which a power source voltage is applied to the phase locked loop circuit 20. When a power source voltage is applied to the phase locked loop circuit 20, variation in the frequency of the periodic signal from the oscillation section 10 due to heat generated by the phase locked loop circuit 20 or a power source variation characteristic can be accurately checked.

When the result of the measurement in step S2 shows that the function of the oscillation section 10 is not satisfactory, the oscillation section 10 is replaced or the function thereof is adjusted.

A conceivable example of the adjustment of the function of the oscillation section 10 is adjustment of the frequency of the resonance section 40.

That is, for example, when the resonance section 40 is an AT-cut crystal oscillation piece, the resonance frequency of the first excitation electrode 44 can be changed by irradiating the first excitation electrode 44 with an ion beam or any other energy beam to adjust the mass of the first excitation electrode 44.

Carrying out step S2 therefore allows the oscillation circuit 11 to output a high-precision periodic signal.

Thereafter, in step S3, the switching section 30 sets the first and second inter-terminal segments 32, 33 in such a way that the first inter-terminal segment 32 is switched to the non-conducting state and the second inter-terminal segment 33 is switched to the conducting state. The signal generation apparatus 200 can output the periodic signal from the phase locked loop circuit 20 or an electric signal processed by using the periodic signal to the terminal portion 55.

As described above, the signal generation circuit 100 and the signal generation apparatus 200 according to the present embodiment can provide the following advantageous effect.

Even when the oscillation section 10 and the phase locked loop circuit 20 are connected to each other, no dedicated terminal portion through which the periodic signal from the oscillation section 10 is outputted is used to output the periodic signal, but the periodic signal from the oscillation section 10 can be measured in consideration of an influence of the phase locked loop circuit 20. As a result, the function of the oscillation section 10 can be accurately checked.

Therefore, since the phase locked loop circuit 20, which uses the oscillation section 10 having an excellent function as a reference signal source, can output a high-precision periodic signal, each of the signal generation circuit 100 and signal generation apparatus 200 provided in accordance with the present embodiment can output a high-precision signal with an increase in the size thereof suppressed.

### Second Embodiment

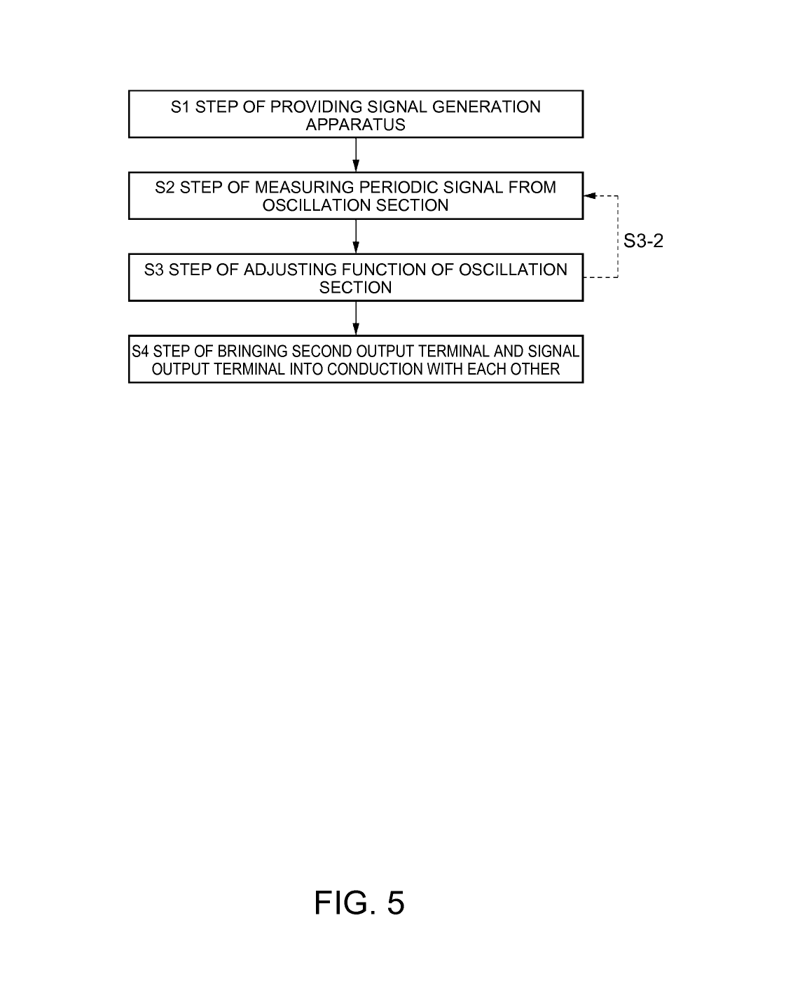

FIG. 4 shows a signal generation circuit according to a second embodiment. FIG. 5 shows a method for manufacturing a signal generation apparatus.

A signal generation circuit 300 according to the present embodiment will be described with reference to FIGS. 4 and 5. The same constituent portions as those in the first embodiment have the same reference numerals, and no redundant description thereof will be made.

The signal generation circuit 300 according to the second embodiment shown in FIG. 4 differs from the signal generation circuit 100 according to the first embodiment in that the oscillation section 10 includes a control circuit 13.

Further, a signal supply terminal 14, through which a control signal for changing the function of the control circuit 13 is inputted, may be provided as required. In this case, the signal supply terminal 14 is brought into conduction, for example, with the terminal portion 56 shown in FIG. 2B. The signal supply terminal 14 is not necessarily provided, and the control section 34 may supply a control signal. In this case, the number of terminals can be reduced.

The control circuit 13 controls a characteristic of the periodic signal outputted by the oscillation section 10. The control circuit 13 is, for example, a voltage control circuit that controls the power source voltage applied to the oscillation circuit 11 or any other voltage value, a frequency/temperature compensation circuit that has a function of compensating dependence of frequency of the resonance section 40 on temperature, a level control circuit that controls the voltage or current level of the sync signal, a circuit constant control circuit that controls electrical characteristics of a circuit element necessary to drive the oscillation circuit 11, and a temperature control circuit that controls a heat generation section and the amount of heat generated by the heat generation section.

When the resonance section 40, the oscillation circuit 11, and the control circuit 13 are brought into conduction with each other in a desired manner, the oscillation section 10 can provide an oscillation function. The oscillation section 10 is, for example, a temperature compensated crystal oscillator (TCXO) or any other temperature compensated oscillator, an oven controlled crystal oscillator (OCXO) or any other temperature controlled oscillator, or an atomic oscillator using a CPT (coherent population trapping) phenomenon.

The control circuit 13 may be a circuit that allows the oscillation circuit 11 to adjust and control a characteristic of the periodic signal outputted therefrom or a circuit that receives the periodic signal outputted by the oscillation circuit 11, controls the supplied periodic signal, and outputs the controlled periodic signal to the first output terminal 12.

The control circuit 13, when it has the frequency-temperature compensation circuit described above, includes a circuit element for temperature detection, such as a thermistor or a diode. The thermistor may be part of (built in) the semiconductor integrated device 60 or separate therefrom. When a circuit element for temperature detection is built in the semiconductor integrated device 60, the function of the oscillation section 10 can be adjusted in consideration of heat generated from a peripheral circuit for the oscillation section 10, whereby the function of the oscillation section 10 can be precisely controlled.

Further, the control circuit 13 may be formed, for example, of a logic circuit and may include a storage device, such as an EEPROM (electrically erasable programmable read-only memory).

A method for manufacturing the signal generation circuit 200 including the thus configured signal generation circuit 300 will be described with reference to FIG. 5.

First, in step S1, the signal generation apparatus 200 assembled, for example, as shown in FIGS. 2A and 2B is provided.

Next, in step S2, the periodic signal from the oscillation section 10 outputted via the signal output terminal 31 and through the terminal portion 55 is measured. In this process, the switching section 30 sets the first and second inter-terminal segments 32, 33 in such a way that the first inter-terminal segment 32 is conducting but the second inter-terminal segment 33 is not conducting (which means that no signal from phase locked loop circuit 20 is transmitted).

In the signal generation apparatus 200, the setting described above made by the switching section 30 may be made after the signal generation apparatus 200 is assembled. However, making the setting described above before the signal generation apparatus 200 is assembled but when the semiconductor integrated device 60 is formed eliminates the necessity to control the switching section 30 after the signal generation apparatus 200 is assembled, whereby it is expected that manufacturing efficiency is improved.

Further, in step S2, the function of the phase locked loop circuit 20 may be activated, but the function is desirably disabled.

In this case, the state in which the function of the phase locked loop circuit 20 is disabled does not necessarily strictly require that no power source voltage is applied to the phase locked loop circuit 20 but the phase locked loop circuit 20 only needs to produce no periodic signal. When the function of the phase locked loop circuit 20 is enabled, the periodic signal from the oscillation section 10 is mixed with a noise signal produced by the phase locked loop circuit 20, and precision of the measurement undesirably decreases. Disabling the function of the phase locked loop circuit 20 can avoid the situation described above.

It is noted that the signal generation apparatus 200 can be manufactured irrespective of the state of the phase locked loop circuit 20, that is, the state in which the function of the phase locked loop circuit 20 is disabled and the state in which a power source voltage is applied to the phase locked loop circuit 20. When a power source voltage is applied to the phase locked loop circuit 20, variation in the frequency of the periodic signal from the oscillation section 10 due to heat generated by the phase locked loop circuit 20 or a power source variation characteristic can be accurately checked.

When the result of the measurement in step S2 shows that the function of the oscillation section 10 is not satisfactory, the oscillation section 10 is replaced or the function thereof is adjusted in step S3 as required.

In this case, in addition to the adjustment of the function having been described with reference to FIG. 3, for example, a control signal is inputted through the terminal portion 56 shown in FIG. 2B to the control circuit 13 to adjust a condition under which the control circuit 13 is set. For example, the function of any of the following circuits provided in accordance with required performance is controlled and adjusted: a voltage control circuit that controls the power source voltage applied to the oscillation circuit 11 or any other voltage value, a frequency/temperature compensation circuit that has a function of compensating dependence of the frequency of the resonance section 40 on temperature, a level control circuit that controls the voltage or current level of the sync signal, and a circuit constant control circuit that controls electrical characteristics of a circuit element necessary to drive the oscillation circuit 11.

After the function of the oscillation section 10 is adjusted in step S3, step S3-2, in which the control returns to step S2, may be carried out as required, and the periodic signal from the oscillation section 10 may be measured again in step S2. Further, the procedure of proceeding from step S2 to step S3 and then returning to step S2 may be repeated as required.

After the function of the oscillation section 10 is appropriately adjusted in step S3, the switching section 30 sets the first and second inter-terminal segments 32, 33 in such a way that the first inter-terminal segment 32 is switched to the non-conducting state and the second inter-terminal segment 33 is switched to the conducting state. The signal generation apparatus 200 can output the periodic signal from the phase locked loop circuit 20 through the terminal portion 55 or an electric signal processed by using the periodic signal to the terminal portion 55.

As described above, the signal generation circuit 300 and the signal generation apparatus 200 according to the present embodiment can provide the following advantageous effect.

Even when the oscillation section 10 and the phase locked loop circuit 20 are connected to each other, no dedicated terminal portion through which the periodic signal from the oscillation section 10 is outputted is used to output the periodic signal, but the periodic signal from the oscillation section 10 can be measured in consideration of an influence of the phase locked loop circuit 20. As a result, the function of the oscillation section 10 can be accurately checked. The result of the checking can be used to precisely control the function of the oscillation section 10.

Therefore, since the phase locked loop circuit 20, which uses the oscillation section 10 having an excellent function as a reference signal source, can output a high-precision periodic signal, each of the signal generation circuit 300 and signal generation apparatus 200 provided in accordance with the present embodiment can output a high-precision signal with an increase in the size thereof suppressed.

The invention is not limited to the embodiments described above, and a variety of changes, improvements, and other modifications can be made to the embodiments described above. Variations follow.

### Variation 1

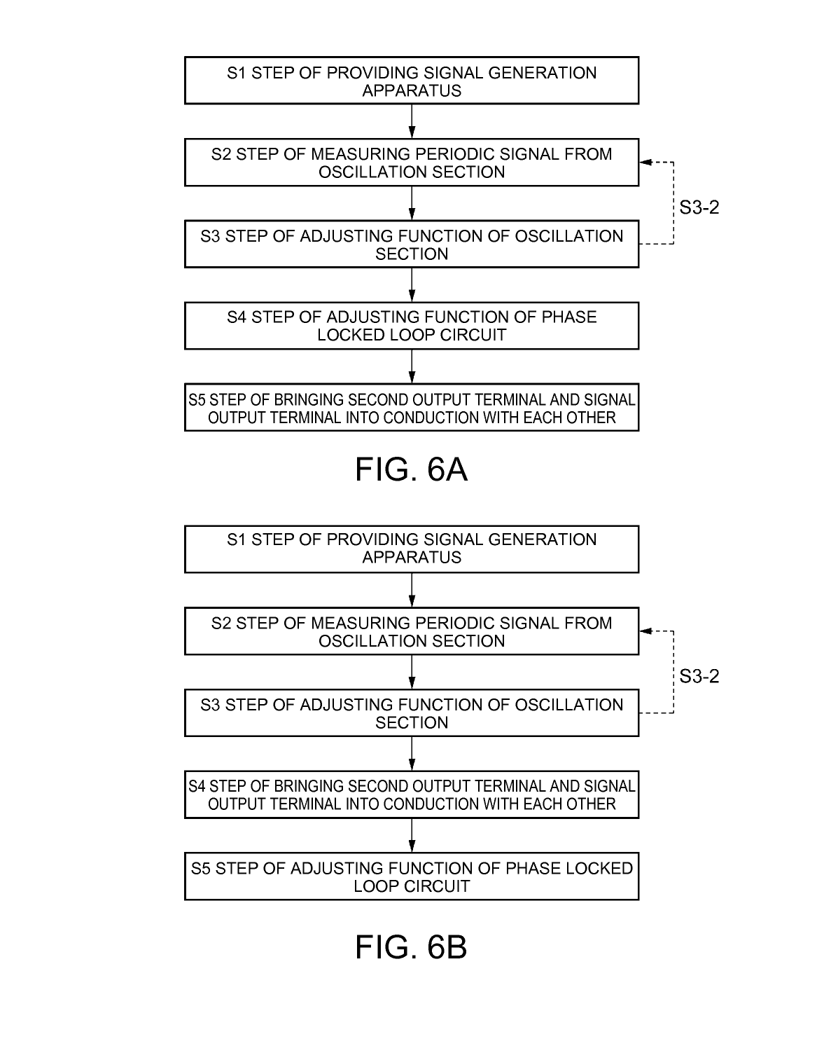

FIGS. 6A and 6B describe methods for manufacturing a signal generation apparatus according to Variation 1.

In the first and second embodiments described above, no description has been made of the step of adjusting the function of the phase locked loop circuit 20, but the invention is not necessarily configured this way.

Methods for manufacturing a signal generation circuit according to Variation 1 will be described below. No redundant description will be made of the same portions as those in the first and second embodiments described with reference to FIGS. 3 and 5.

The methods for manufacturing a signal generation apparatus shown in FIGS. 6A and 6B differ from the manufacturing methods shown in FIGS. 3 and 5 in that the step of adjusting the function of the phase locked loop circuit 20 is placed after step S3. In FIG. 6A, the step of adjusting the function of the phase locked loop circuit is named step S4 and placed between step S3 and step S5, where the second output terminal and the signal output terminal are brought into conduction with each other.

In FIG. 6B, the step of adjusting the function of the phase locked loop circuit is placed after step S4, where the second output terminal and the signal output terminal are brought into conduction with each other.

To adjust the function of the phase locked loop circuit, the control section 34 may be used. Since the step described above allows adjustment of the function of the phase locked loop circuit 20 in accordance with the oscillation section 10 the function of which has been adjusted, a signal generation apparatus that outputs a high-precision signal can be provided.

The phase locked loop circuit 20 is classified into an integer-N type based on integer division and a fractional-N type based on fractional division. In the step of precisely adjusting the function of the phase locked loop circuit 20 in accordance with the function of the oscillation section 10 as described above, it is preferable to use a fractional-N-type phase locked loop circuit 20, which can minutely change the frequency of the periodic signal.

As described above, the methods for manufacturing a signal generation apparatus according to the present variation can provide the following advantageous effect in addition to the advantageous effects provided by the first and second embodiments.

That is, since the step described above allows more exact adjustment of the function of the phase locked loop circuit 20 in accordance with the oscillation section 10 the function of which has been adjusted, a signal generation apparatus that outputs a high-precision signal can be provided.

### Variation 2

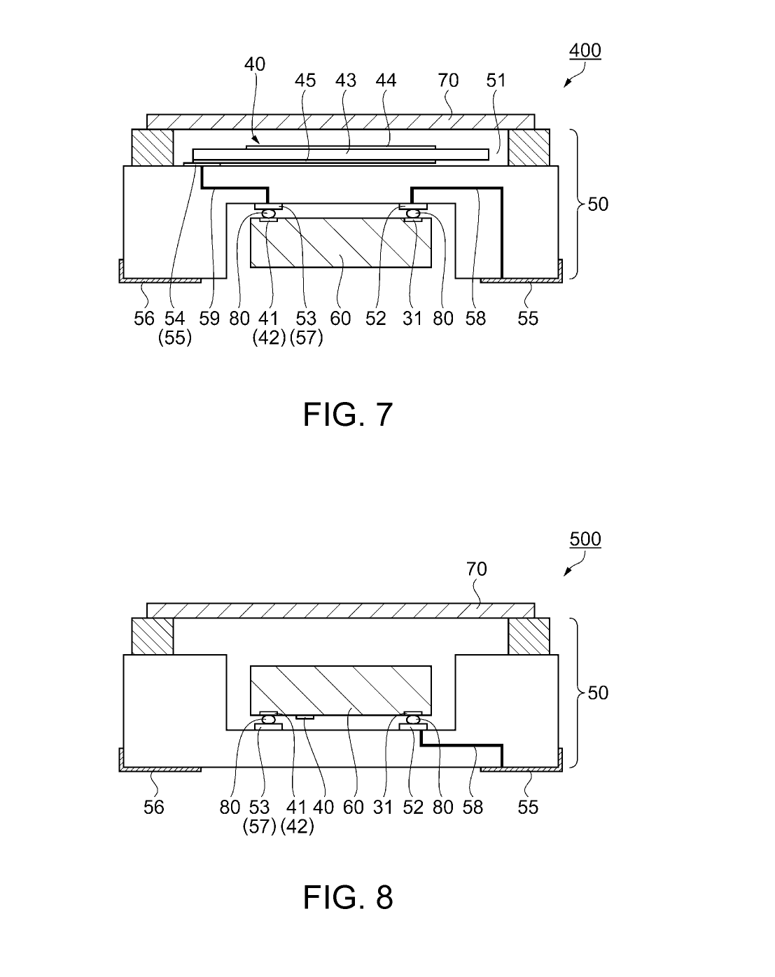

FIG. 7 describes a signal generation apparatus according to Variation 2.

In the first and second embodiments described above, the resonance section 40 and the semiconductor integrated device 60 are accommodated in the same accommodation space as shown in FIG. 2B, but the invention is not necessarily configured this way.

A signal generation apparatus 400 according to Variation 2 will be described below. No redundant description will be made of the same portions as those of the signal generation apparatus 200 shown in FIGS. 2A and 2B.

The signal generation apparatus 400 shown in FIG. 7 differs from the signal generation apparatus 200 shown in FIGS. 2A and 2B in terms of the configuration of the wiring substrate 50 and the positional relationship between the resonance section 40 and the semiconductor integrated device 60.

That is, in the signal generation apparatus 400, the resonance section 40 and the semiconductor integrated device 60 are both still mounted on the wiring substrate 50, but the resonance section 40 is disposed in the recess 51 whereas the semiconductor integrated device 60 is disposed on a rear surface of the wiring substrate 50 or a surface thereof facing away from the recess 51.

The signal generation apparatus according to the present variation described above can provide the same advantageous effects provided by the first and second embodiments.

### Variation 3

FIG. 8 describes a signal generation apparatus according to Variation 3.

In the first and second embodiments described above, the resonance section 40 and the semiconductor integrated device 60 are components separate from each other as shown in FIGS. 2B and 7, but the invention is not necessarily configured this way.

A signal generation apparatus 500 according to Variation 3 will be described below. No redundant description will be made of the same portions as those of the signal generation apparatus 200 shown in FIGS. 2A and 2B.

The signal generation apparatus 500 shown in FIG. 8 differs from the signal generation apparatus 200 shown in FIGS. 2A and 2B in that the resonance section 40 is disposed on the semiconductor integrated device 60 or built therein.

That is, the signal generation apparatus 500 includes a semiconductor integrated device 60 that accommodates a resonance section 40 formed based on a MEMS (micro electro mechanical systems) technology.

As described above, the signal generation apparatus according to the present variation can provide the following advantageous effect in addition to the advantageous effects provided by the first and second embodiments.

That is, the resonance section 40, which is built in the semiconductor integrated device 60, is likely to be influenced, for example, by heat from the oscillation circuit 11 and peripheral circuits, such as the phase locked loop circuit 20.

The periodic signal from the oscillation section 10 is therefore influenced by the peripheral circuits. Therefore, the function of the oscillation section 10 can be adjusted in consideration of compensation of the influence of the peripheral circuits, and employing either of the manufacturing methods shown in FIGS. 6A and 6B allows the function of the phase locked loop circuit 20 to be more exactly adjusted in consideration of the influence of the resonance section 40, whereby a signal generation apparatus that outputs a high-precision signal can be provided.

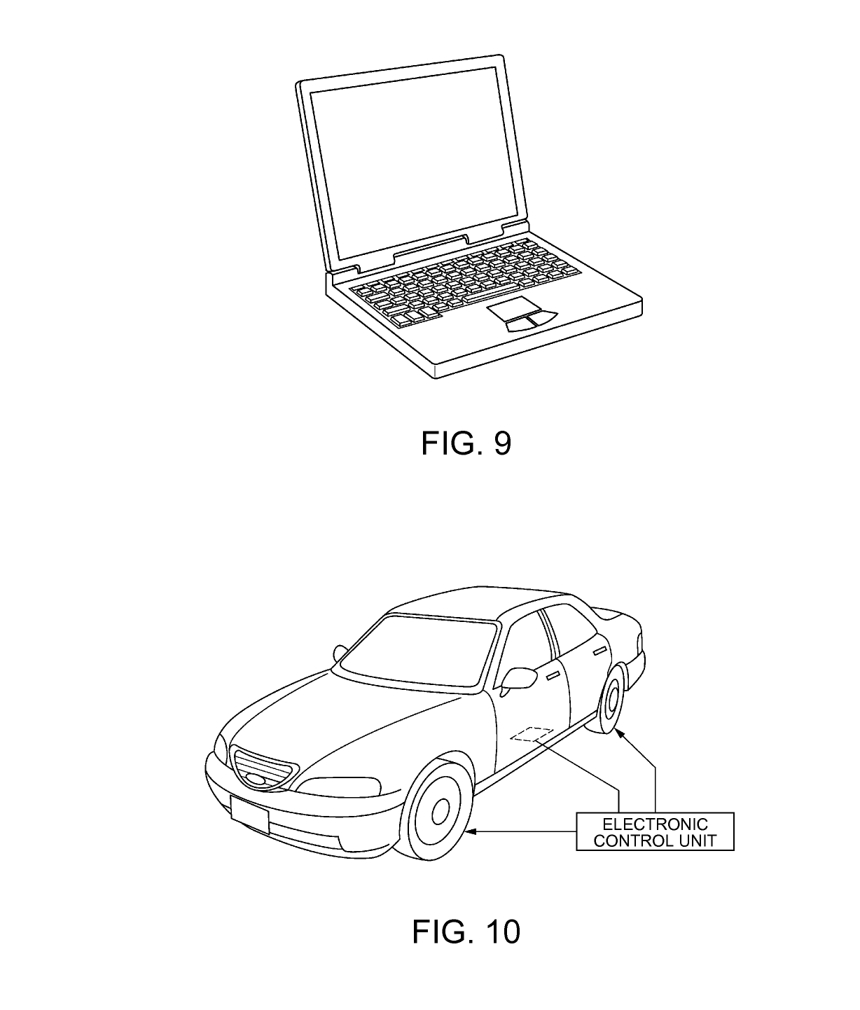

An electronic apparatus including the signal generation circuit according to any of the embodiments of the invention can be not only a personal computer (mobile personal computer) shown in FIG. 9, a mobile phone, and a digital still camera but also, for example, an inkjet-type liquid ejection apparatus (inkjet printer, for example), a laptop personal computer, a television receiver, a video camcorder, a video tape recorder, a car navigation system, a pager, an electronic notebook (including electronic notebook having communication capability), an electronic dictionary, a desktop calculator, an electronic game console, a word processor, a workstation, a TV phone, a security television monitor, electronic binoculars, a POS terminal, medical apparatus (such as electronic thermometer, blood pressure gauge, blood sugar meter, electrocardiograph, ultrasonic diagnostic apparatus, and electronic endoscope), a fish finder, a variety of measuring apparatus, a variety of instruments (such as instruments in vehicles, airplanes, and ships), and a flight simulator.

FIG. 10 is a perspective view schematically showing an automobile as an example of a moving object. The automobile includes the signal generation circuit according to any of the embodiments of the invention. For example, the automobile as a moving object, specifically, a vehicle body accommodates an electronic control unit that controls the wheels, as shown in FIG. 10. In addition, the signal generation circuit according to any of the embodiments of the invention can be widely used as a keyless entry system, an immobilizer, a car navigation system, a car air conditioner, an antilock brake system (ABS), an airbag, a tire pressure monitoring system (TPMS), an engine control system, an apparatus that monitors a battery in a hybrid automobile and an electric automobile, a vehicle body attitude control system, and any other electronic control unit (ECU).

The entire disclosure of Japanese Patent Application No. 2013-122566, filed Jun. 11, 2013 is expressly incorporated by reference herein

What is claimed is:

1. A signal generation circuit comprising:
an oscillation section including an oscillation circuit, a first output terminal through which a periodic signal is outputted, and a control circuit used to control a characteristic of the periodic signal and capable of changing a function of performing the control;
a phase locked loop circuit so brought into conduction with the first output terminal that the oscillation section serves as a reference signal source and including a second output terminal; and
a switching section including a signal output terminal and switching the state of a segment between the first output terminal and the signal output terminal from a conducting state to a non-conducting state and switching the state of a segment between the second output terminal and the signal output terminal to the conducting state.

2. The signal generation circuit according to claim 1,
further comprising a resonance section that supplies a resonance signal to the oscillation circuit.

3. A signal generation apparatus comprising:
an oscillation section including an oscillation circuit, a first output terminal through which a periodic signal is outputted, and a control circuit that controls a characteristic of the periodic signal;
a phase locked loop circuit so brought into conduction with the first output terminal that the oscillation section serves as a reference signal source and including a second output terminal;
a switching section including a signal output terminal, disposed in a first inter-terminal segment between the first output terminal and the signal output terminal and in a second inter-terminal segment between the second output terminal and the signal output terminal, and switching the state of a selected one of the inter-terminal segments to a conducting state and switching the state of the other inter-terminal segment to a non-conducting state; and
a wiring substrate on which the oscillation section, the phase locked loop circuit, and the switching section are mounted and which has a terminal portion brought into conduction with the signal output terminal.

4. The signal generation apparatus according to claim 3,
wherein the oscillation circuit, the phase locked loop circuit, and the switching section are provided in a single semiconductor substrate.

5. The signal generation apparatus according to claim 3,
further comprising a resonance section that supplies a resonance signal to the oscillation circuit.

6. The signal generation apparatus according to claim 3,
wherein the switching section keeps the state of the second inter-terminal segment conducting.

7. A method for manufacturing a signal generation apparatus, the method comprising:
providing a signal generation apparatus including
an oscillation section having a resonance section, an oscillation circuit to which a resonance signal from the resonance section is supplied, and a first output terminal through which a periodic signal is outputted,
a phase locked loop circuit so brought into conduction with the first output terminal that the oscillation section serves as a reference signal source and having a second output terminal, and
a switching section having a signal output terminal and switching a state in which the first output terminal and the signal output terminal are brought into conduction with each other;
outputting the periodic signal from the oscillation section through the signal output terminal and measuring the periodic signal in the state in which the first output terminal and the signal output terminal are brought into conduction with each other; and
controlling the switching section to switch the state of a segment between the first output terminal and the signal output terminal to a non-conducting state and switching the state of a segment between the second output terminal and the signal output terminal to a conducting state.

8. The method for manufacturing a signal generation apparatus according to claim 7,
further comprising adjusting a function of the oscillation section after the measurement of the periodic signal.

9. The method for manufacturing a signal generation apparatus according to claim 8,
further comprising adjusting a function of the phase locked loop circuit after the adjustment of the function of the oscillation section.

10. The method for manufacturing a signal generation apparatus according to claim 7,
wherein a function of the phase locked loop circuit is disabled in the measurement of the periodic signal.

11. The method for manufacturing a signal generation apparatus according to claim 7,
wherein a power source voltage is supplied to the phase locked loop circuit in the measurement of the periodic signal.

12. An electronic apparatus comprising the signal generation circuit according to claim 1.

13. A moving object comprising the signal generation circuit according to claim 1.
